(19) United States
(12) Patent Application Publication
(10) Pub. No.: US 2015/0126027 A1
(43) Pub. Date: May 7, 2015

(54) METHOD FOR MANUFACTURING SEMICONDUCTOR DEVICE

(71) Applicant: TOKYO ELECTRON LIMITED, Tokyo (JP)

(72) Inventors: Kenji MATSUMOTO, Nirasaki-shi (JP); Tatsufumi HAMADA, Nirasaki-shi (JP); Kaoru MAEKAWA, New York, NY (US)

(21) Appl. No.: 14/598,788

(22) Filed: Jan. 16, 2015

Related U.S. Application Data
(63) Continuation of application No. PCT/JP2013/069058, filed on Jul. 11, 2013.

(30) Foreign Application Priority Data
Jul. 18, 2012 (JP) 2012-159652

(51) Int. Cl. H01L 21/768

(52) U.S. Cl. CPC H01L 21/76843; H01L 21/76802; H01L 21/76855
USPC 438/652

(57) ABSTRACT

A method for manufacturing a semiconductor device includes: forming an insulating film on a substrate where a first conductive film is formed; forming a recess in the insulating film such that the first conductive film is exposed in a portion of the recess; forming a metal oxide film to cover the insulating film and the first conductive film after forming a recess; performing a hydrogen radical treatment of irradiating the substrate with atomic hydrogen after forming a metal oxide film; and forming a second conductive film in the recess.

### CROSS-REFERENCE TO RELATED APPLICATIONS

This application is a Continuation application of PCT International Application No. PCT/JP2013/069058, filed Jul. 11, 2013, which claimed the benefit of Japanese Patent Application No. 2012-159652, filed Jul. 18, 2012, the entire content of each of which is hereby incorporated by reference.

### TECHNICAL FIELD

The present disclosure relates to a method for manufacturing a semiconductor device.

### BACKGROUND

Recently, it is required to produce a compact-sized electronic device having high speed and high reliability. To this end, a multilayer wiring structure in which a metal wiring is embedded in an interlayer insulating film by a damascene method is widely employed to obtain a miniaturized semiconductor device featuring high speed and high integration. Copper (Cu), which has low electromigration and low resistance, is generally used as a material for the metal wiring. The multilayer wiring structure is formed in the following sequence. First, a recess such as a trench is formed by removing an interlayer insulating film on a certain region until a wiring provided under the interlayer insulating film is exposed. Then, in order to suppress diffusion of the copper into the interlayer insulating film or the like, a barrier film is formed in the recess. Thereafter, a copper-containing film is buried to be formed on the barrier film in the recess.

Typically, tantalum (Ta), tantalum nitride (TaN) or the like is used as the barrier film. Recently, however, a technique using manganese oxide (MnOx) has been proposed to obtain a thin and highly uniform film. There has been proposed a method of forming an embedded electrode made of Cu on the MnOx film. Further, in order to increase the adhesion with Cu, there has been proposed a method of forming, on the MnOx film, a ruthenium (Ru) film having high adhesiveness to Cu and then forming an embedded electrode made of Cu on the Ru film.

However, when the MnOx film is formed by ALD (Atomic Layer Deposition), since a reaction between a Mn precursor and H₂O causes the MnOx film to be formed, the MnOx film is formed not only on a side surface of the recess but also on a bottom surface of the recess where Cu is exposed. In addition, even when a Mn film is formed by thermal CVD (Chemical Vapor Deposition) or plasma enhanced CVD, if a native oxide film (CuOx) on the Cu surface is not completely removed but remains on the Cu surface, a reaction between the formed metal Mn and the CuOx causes a MnOx film to be also formed on the bottom surface of the recess where Cu is exposed. Since the MnOx film thus formed has high resistance compared with metal such as Cu, even if the embedded electrode made of Cu is formed on the MnOx film, sufficient conductivity cannot be obtained due to interposition of the MnOx film, resulting in poor conductivity.

### SUMMARY

Some embodiments of the present disclosure provide a method for manufacturing a semiconductor device, in which a recess such as a trench is formed in an insulating film, a metal oxide film such as a MnOx film is formed in the recess, and a conductive film such as Cu is formed thereon, whereby sufficient conductivity, desired properties, and high production yield can be obtained.

According to an embodiment of the present disclosure, a method for manufacturing a semiconductor device is provided. The method includes: forming an insulating film on a substrate where a first conductive film is formed; forming a recess in the insulating film such that the first conductive film is exposed in a portion of the recess; forming a metal oxide film to cover the insulating film and the first conductive film after forming a recess; performing a hydrogen radical treatment of irradiating the substrate with atomic hydrogen after forming a metal oxide film; and forming a second conductive film in the recess.

According to another embodiment of the present disclosure, a method for manufacturing a semiconductor device is provided. The method includes: forming an insulating film on a substrate where a first conductive film is formed; forming a recess in the insulating film such that the first conductive film is exposed in a portion of the recess; forming a metal oxide film to cover the insulating film and the first conductive film after forming a recess; performing an annealing process of heating the substrate in a reducing atmosphere or an inert gas atmosphere after forming a metal oxide film; performing a hydrogen radical treatment to irradiate the substrate with atomic hydrogen after performing an annealing process; and forming a second conductive film in the recess after performing a hydrogen radical treatment.

According to another embodiment of the present disclosure, a method for manufacturing a semiconductor device is provided. The method includes: forming an insulating film on a substrate where a first conductive film is formed; forming a recess in the insulating film such that the first conductive film is exposed in a portion of the recess; forming a metal oxide film to cover the insulating film and the first conductive film after forming a recess; performing an annealing process of heating the substrate in a reducing atmosphere or an inert gas atmosphere after forming a metal oxide film is formed; performing a wet etching process of removing the metal oxide film formed on the first conductive film after performing an annealing process; and forming a second conductive film in the recess after performing a wet etching process.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a configuration view of a semiconductor device manufacturing apparatus in accordance with a first embodiment of the present disclosure.

FIG. 2 is a configuration view of another semiconductor device manufacturing apparatus in accordance with the first embodiment of the present disclosure.

FIG. 3 is a view illustrating a method for manufacturing a semiconductor device in the first embodiment of the present disclosure.

FIGS. 4A to 4C illustrate a processing diagram 1 of the method for manufacturing the semiconductor device in the first embodiment of the present disclosure.

FIGS. 5A to 5C illustrate a processing diagram 2 of the method for manufacturing the semiconductor device in the first embodiment of the present disclosure.

FIG. 6 is a processing diagram 3 of the method for manufacturing the semiconductor device in the first embodiment of the present disclosure.

FIG. 7 is a view illustrating a method for manufacturing a semiconductor device in a second embodiment of the present disclosure.

FIGS. 8A to 8C illustrate a processing diagram 1 of the method for manufacturing the semiconductor device in the second embodiment of the present disclosure.

FIGS. 9A to 9C illustrate a processing diagram 2 of the method for manufacturing the semiconductor device in the second embodiment of the present disclosure.

FIG. 10 is a processing diagram 3 of the method for manufacturing the semiconductor device in the second embodiment of the present disclosure.

FIG. 11 is a view illustrating a method for manufacturing a semiconductor device in a third embodiment of the present disclosure.

FIGS. 12A to 12C illustrate a processing diagram 1 of the method for manufacturing the semiconductor device in the third embodiment of the present disclosure.

FIGS. 13A to 13C illustrate a processing diagram 2 of the method for manufacturing the semiconductor device in the third embodiment of the present disclosure.

FIGS. 14A and 14B illustrate a processing diagram 3 of the method for manufacturing the semiconductor device in the third embodiment of the present disclosure.

FIG. 15 is a view illustrating a method for manufacturing a semiconductor device in a fourth embodiment of the present disclosure.

FIGS. 16A to 16C illustrate a processing diagram 1 of the method for manufacturing the semiconductor device in the fourth embodiment of the present disclosure.

FIGS. 17A to 17C illustrate a processing diagram 2 of the method for manufacturing the semiconductor device in the fourth embodiment of the present disclosure.

FIG. 18 is a processing diagram 3 of the method for manufacturing the semiconductor device in the fourth embodiment of the present disclosure.

FIG. 19 is an explanatory view 1 illustrating a wet etching process.

FIGS. 20A and 20B are explanatory views 2 illustrating the wet etching process.

### DETAILED DESCRIPTION

Hereinafter, details for performing the present disclosure will be described with reference to the accompanying drawings. The present disclosure is not limited to the following embodiments, and various modifications and replacements can be made to the following embodiments without departing from the scope of the present disclosure.

In addition, like parts will be assigned like reference numerals, and redundant description will be omitted. Further, a manganese oxide may be in the form of, but not limited to, MnO, Mn₃O₄, Mn₂O₃, MnO₂ or the like depending on a valence number. Here, unless otherwise stated, all of these forms are represented by MnO. When the manganese oxide is represented by MnOₓ, x denotes a number between 1 and 2 inclusive. A Mn silicate may be in the form of Mn₂SiO₄ or Mn₇SiO₁₂ in addition to MnSiO₃. Here, unless otherwise stated, all of these forms are represented by MnSixOy, wherein x and y denote positive numbers.

Further, in the embodiments, a hydrogen radical treatment indicates a process of generating atomic hydrogen by remote plasma, plasma, a heating filament or the like and irradiating a predetermined surface of a substrate or the like with the generated atomic hydrogen.

Further, in the embodiments, for a conversion process into a silicate by reacting with SiO₂ of an underlying layer by an annealing (heat treatment) process, when an object to be processed is Mn, MnSiO₃ is formed by an O₂ annealing process. In the case of MnO, MnSiO₃ is formed by an inert gas annealing process. In case of Mn₃O₄, Mn₂O₃ or MnO₂, MnSiO₃ is formed by a reducing atmosphere annealing process using a reducing gas such as hydrogen, CO, amine or its analogues (NR¹R²R³), hydrazine or its analogues (N₂R⁴R⁵R⁶R⁷) (wherein R¹ to R⁷ are hydrogen (H) or hydrocarbon). The present disclosure is based on the above-described knowledge.

### First Embodiment

### Semiconductor Device Manufacturing Apparatus

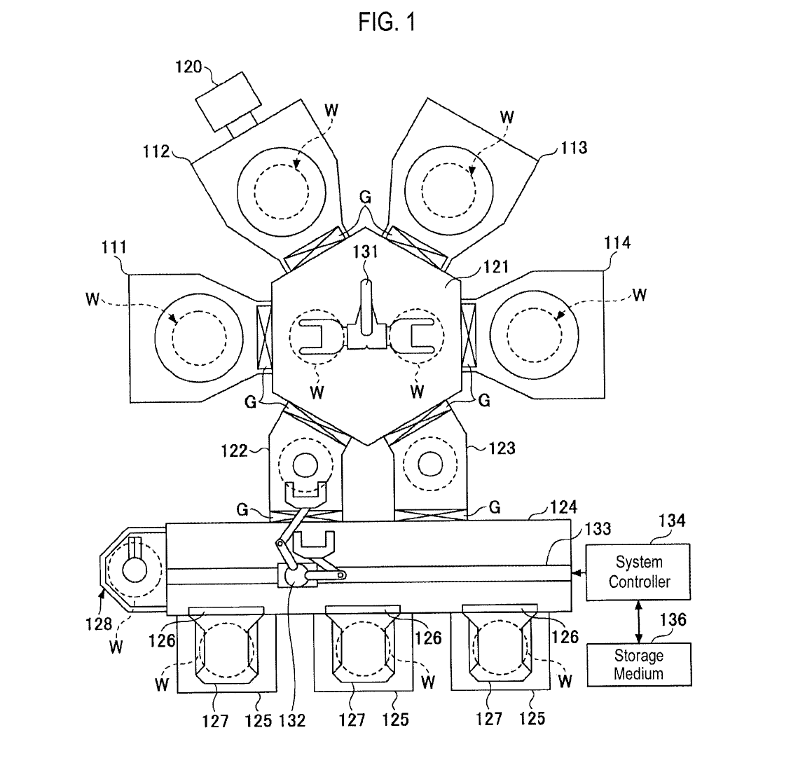

A semiconductor device manufacturing apparatus in accordance with an embodiment will be described. A wafer W may refer to a substrate or a substrate on which a film is formed. FIG. 1 illustrates a processing system used as the semiconductor device manufacturing apparatus in accordance with the embodiment. The processing system includes four processing apparatuses 111, 112, 113 and 114; a substantially hexagonal common transfer chamber 121; a first load lock chamber 122 and a second load lock chamber 123 having a load lock function; and an elongated narrow inlet side transfer chamber 124. Gate valves G are provided between the hexagonal common transfer chamber 121 and the processing apparatuses 111 and 114, respectively. Gate valves G are also provided between the common transfer chamber 121 and each of the first and second load lock chambers 122 and 123, respectively. Further, Gate valves G are provided between the inlet side transfer chamber 124 and each of the first and second load lock chambers 122 and 123. Each of the gate valves G can be opened and closed, and wafers W can be transferred between, e.g., the respective apparatuses, by opening the gate valves G. By way of non-limiting example, three inlet ports 125 are connected to the inlet side transfer chamber 124 via opening/closing doors 126, and a cassette receptacle 127 configured to accommodate a plurality of wafers W is mounted in each inlet port 125. Further, an orienter 128 is provided at the inlet side transfer chamber 124 to perform alignment of the wafers W.

A transfer mechanism 131 having a pickup that can be bended and extended to transfer wafers W is provided in the common transfer chamber 121. Further, an inlet side transfer mechanism 132 having a pickup that can be bended and extended to transfer wafers W is provided in the inlet side transfer chamber 124. The inlet side transfer mechanism 132 is supported on a guide rail 133 provided in the inlet side transfer chamber 124 to move slidably along the guide rail 133.

A wafer W is, by way of example, but not limitation, is a silicon wafer and is accommodated in the cassette receptacle 127. The wafer W is transferred from the inlet port 125 into the first load lock chamber 122 or the second load lock chamber 123 by the inlet side transfer mechanism 132. Then, the wafer W transferred into the first load lock chamber 122 or the second load lock chamber 123 is transferred into the four processing apparatuses 111 to 114 by the transfer mechanism 131 provided in the common transfer chamber 121. Further, the wafer W is also transferred between the four processing apparatuses 111 to 114 by the transfer mechanism 131. As the wafer W is moved between the four processing apparatuses 111 to 114, the wafer W is processed in the respective processing apparatuses 111 to 114. The above-mentioned transfer and processing of the wafer W may be controlled by a system controller 134 (control unit), and programs for implementing the system control or the like are stored in a storage medium 136.

In addition, the system controller 134 is implemented by a CPU of any computer, a memory, a program loaded in the memory, a memory unit for storing the program, such as a hard disc, and any combination of hardware and software through an interface for connecting to networks. Further, it is understood by a person skilled in the art that there are various modifications to its implementing method and apparatus.

In the present embodiment, among the four processing apparatuses 111 to 114, the first processing apparatus 111 is configured to form a MnOx film and includes a gas supply system for supplying film forming raw material gases into a processing space. The second processing apparatus 112 is configured to perform a hydrogen radical treatment, an inert gas annealing process or a reducing atmosphere annealing process and is provided with a gas supply system for supplying necessary gases into a processing space. The third processing apparatus 113 is configured to form a Ru film and is provided with a gas supply system for supplying film forming raw material gases into a processing space. The fourth processing apparatus 114 is configured to form a metal film such as a Cu film and is provided with a gas supply system for supplying film forming raw material gases into a processing space.

Connected to the second processing apparatus 112 is a remote plasma generating unit 120 configured to generate atomic hydrogen. By irradiating the wafer W with the atomic hydrogen that is generated by allowing hydrogen to pass through the remote plasma generating unit 120, a hydrogen radical treatment is performed. Here, it may be possible to employ a configuration in which the plasma generating unit is provided within the second processing apparatus 112 as long as the atomic hydrogen can be generated. Still alternatively, it may be possible to set up a configuration in which a heating filament is provided within the second processing apparatus 112 and atomic hydrogen is generated by heating. In addition, the reducing atmosphere annealing process may be performed in the second processing apparatus 112 by supplying hydrogen into a chamber of the second processing apparatus 112 and heating it. Further, before the MnOx film is formed in the first processing apparatus 111, a pre-process (for example, a degassing process) may be performed on the wafer W in the first processing apparatus 111 or the like. An oxidizing atmosphere annealing process may be performed, for example, in the third processing apparatus 113.

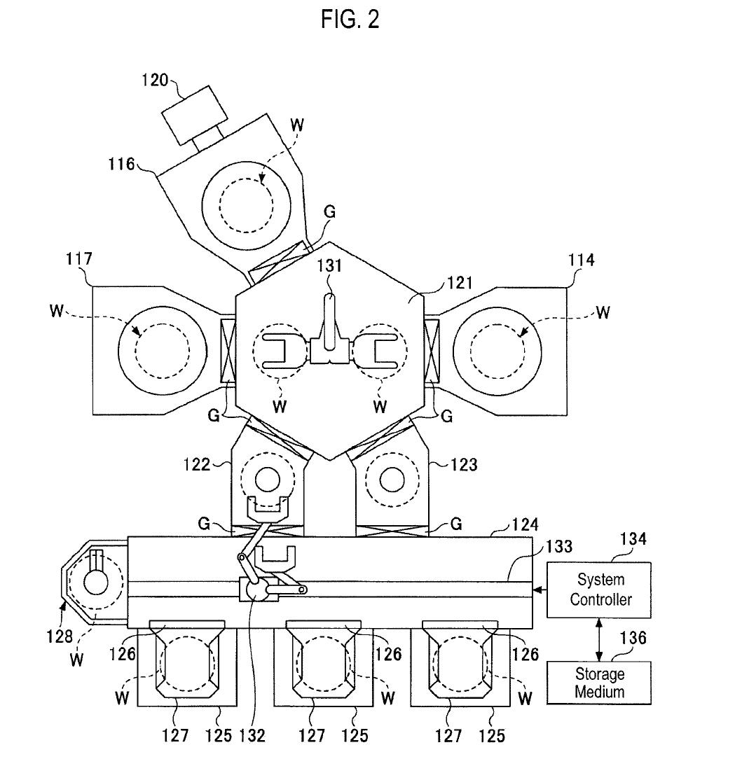

As shown in FIG. 2, the processes performed in the first processing apparatus 111, the second processing apparatus 112 and the third processing apparatus 113 may be performed in a single processing apparatus 116. In this case, the processing apparatus 116 connected to the remote plasma generating unit 120 is coupled to the common transfer chamber 121 via a gate valve G. Further, when performing a pre-process of the wafer W prior to forming the MnOx film or the like, a processing apparatus 117 configured to perform the pre-process (for example, a degassing process) on the wafer W may be provided, as shown in FIG. 2.

### (Method for Manufacturing Semiconductor Device)

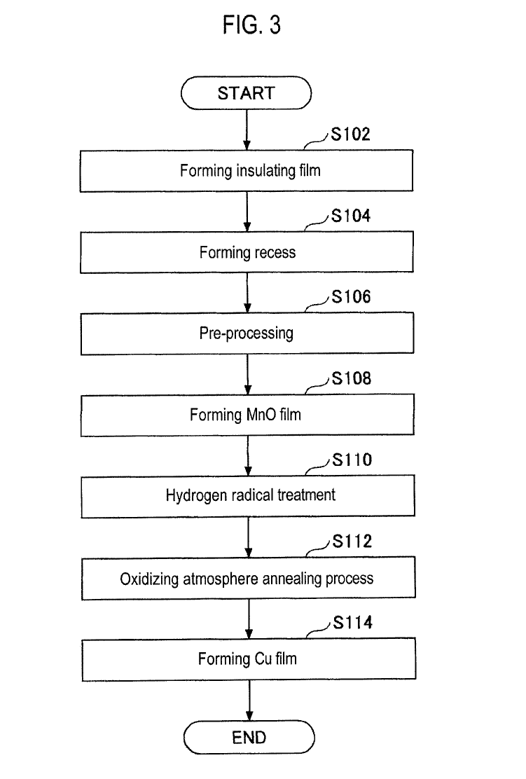

Now, a method for manufacturing a semiconductor device in accordance with the embodiment will be discussed with reference to FIGS. 3, and 4a to 6. The method for manufacturing the semiconductor device of the present embodiment is to manufacture a semiconductor device having a multilayer wiring structure and to form an interlayer wiring structure. Thus, description of a semiconductor device, which has already been formed, and a manufacturing method therefor is omitted here.

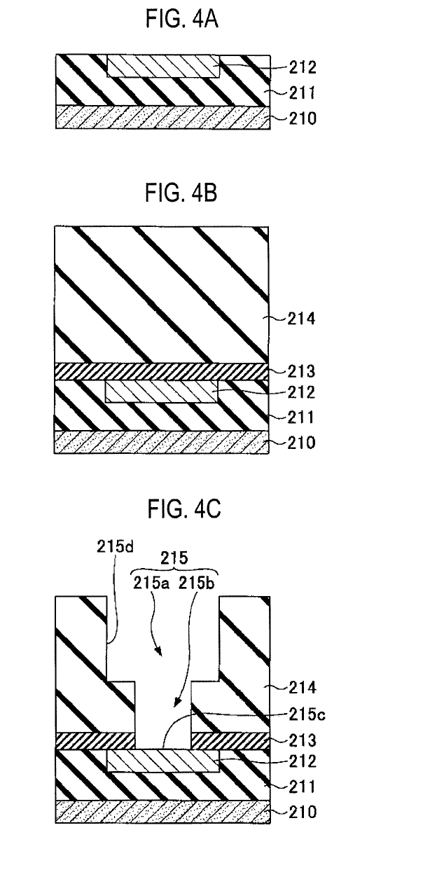

First, at Step S102, an insulating film to be used as an interlayer insulating film is formed (insulating film forming process). Specifically, first, there is prepared a configuration in which a first conductive film (wiring layer) 212 made of copper or the like is formed on a surface of an insulating layer 211 which is formed on a substrate 210 such as a silicon substrate, as illustrated in FIG. 4A. Such a configuration may be formed in the same sequence as a later-described second conductive film (Cu film) 230 (a Mn silicate film 222b, and the like).

Subsequently, stacked on such a configuration are a diffusion preventing film 213 such as SiCN and an insulating film 214 made of SiO₂ or the like to be used as an interlayer insulating film, as shown in FIG. 4B (insulating film forming process). In addition, the insulating film 211 and the insulating film 214 may be formed of TEOS or Low-k containing silicon oxide. In addition, the first conductive film 212 is connected to a non-illustrated transistor and other wirings formed on the surface of the substrate 210 or the like. Here, the main component of the diffusion preventing film 213 may be not only the above-described SiCN but also SiC or SiN. Further, the main component of the insulating film 211 and the insulating film 214 may be not only the above-described TEOS but also SiOC or SiOCH as the Low-k containing silicon oxide. Although a Cu diffusion barrier film is formed between the insulating film 211 and the first conductive film 212, the description thereof is omitted here.

Then, at Step S104, a recess (opening) 215 is formed in the insulating film 214 and the diffusion preventing film 213 (recess forming process). Specifically, as shown in FIG. 4C, a predetermined region of the insulating film 214 and the diffusion preventing film 213 is removed by etching or the like until a surface of the first conductive film 212 is exposed, thereby forming the recess 215. In the embodiment, the recess 215 includes a narrow long groove (trench) 215a, and a via hole 215b formed at a part of the bottom of the groove 215a. The first conductive film 212 is exposed at a bottom 215c of the via hole 215b. By way of example, this recess 215 may be formed by applying photoresist on the surface of the insulating film 214 and then performing repeatedly an exposure process in an exposure apparatus and an etching process such as RIE (Reactive Ion Etching).

Next, at Step S106, a degassing process, a cleaning process or the like is performed as a pre-process, so that the inside of the recess 215 is cleaned. As such a cleaning process, a H₂ annealing process, a H₂ plasma process, an Ar plasma process, and a dry cleaning process using organic acid may be employed.

In addition, the degassing process by heating is performed under the following conditions of: an inert gas atmosphere such as N₂, Ar or He, a wafer temperature of 250 to 400 degrees C., a pressure of 13 to 2670 Pa, and a processing time of 30 to 300 seconds, for example, under the following conditions of: an Ar atmosphere, a wafer temperature of 300 degrees C., a pressure of 1330 Pa, and a processing time of 120 seconds.

Further, removal of native copper oxide by a H₂ annealing process is performed under the following conditions of: a H₂ atmosphere (wherein an inert gas such as N₂, Ar or He may be added thereto, and also, a concentration of H₂ may be 1 to 100 vol %), a wafer temperature of 250 to 400 degrees C., a pressure of 13 to 2670 Pa, and a processing time of 30 to 300 seconds, for example, under the following conditions of: a forming gas (3% H₂+97% Ar) atmosphere, a wafer temperature of 300 degrees C., a pressure of 1330 Pa, and a processing time of 120 seconds.

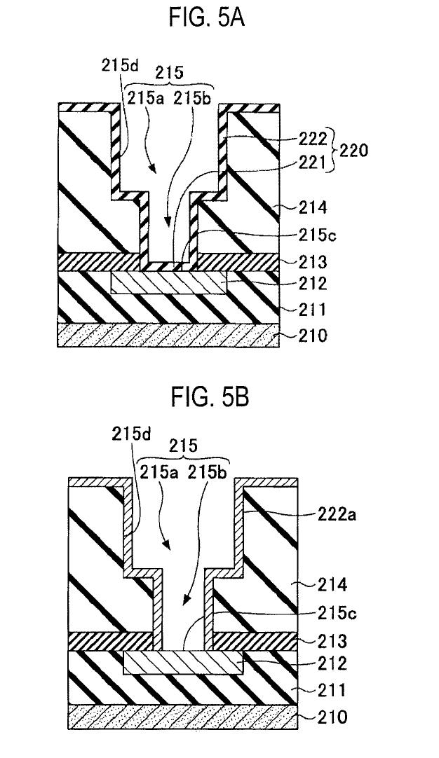

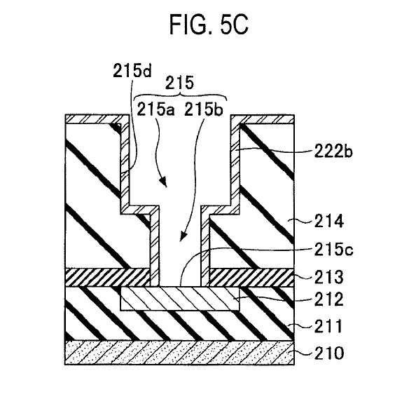

Then, at Step S108, a metal oxide film is formed (metal oxide film forming process). In the embodiment, the metal oxide film may be a film containing Mn, such as a MnOx film. The metal oxide film may be formed by ALD. Specifically, as shown in FIG. 5A, the substrate 210 is heated to a temperature of 100 to 250 degrees C., for example, 130 degrees C., and a MnOx film 220 is formed by alternately supplying a Mn precursor, such as (EtCp)₂Mn, and H₂O. Thus, the MnOx film 220 is formed on the bottom 215c of the via hole 215b, a side surface 215d of the recess 215, and the like. In the embodiment, a portion of the MnOx film 220 formed on the bottom 215c of the via hole 215b will be described as a MnOx film 221, and a portion of the MnOx film 220 formed on the side surface 215d of the recess 215 and the like will be described as a MnOx film 222. In addition, the MnOx film 220 is formed on an upper surface of the insulating film 214, and the MnOx film 220 thus formed will be assumed to be converted in the same manner as the MnOx film 222.

In addition, the MnOx film may be formed by thermal CVD or plasma CVD without limitation to the above-described ALD. In this case, specifically, the substrate 210 is heated to a temperature of 150 to 400 degrees C., for example, 200 degrees C., and the MnOx film is formed by supplying a Mn precursor of (EtCp)₂. Thus, the MnOx film is formed on the side surface 215d of the recess 215 and the like. However, when the native oxide film (CuOx) of the Cu surface is not completely removed but remains, a reaction between the Mn precursor and the CuOx causes the MnOx film to be formed on the bottom surface of the recess at which Cu is exposed.

As a Mn precursor other than (EtCp)₂Mn, the following are used:
Cyclopentadienyl-based manganese compound such as bis(alkylcyclopentadienyl)manganese represented by the general formula Mn(RC₅H₄)₂.
Carbonyl-based manganese compound such as dimanganese decacarbonyl (Mn₂(CO)₁₀) or methyl cyclopentadienyl manganese tricarbonyl ((CH₃C₅H₄)Mn(CO)₃).
Beta-diketone-based manganese compound such as bis(dipivaloylmethanato)manganese (Mn(C₁₁H₁₉O₂)₂).
Amidinate-based manganese compound such as bis(N, N-dialkylacetamidinate)manganese represented by the general formula Mn(R¹N—CR³—NR²)₂ disclosed in U.S. Patent Application Publication No. US2009/0263965A1.
Amideaminoalkane-based manganese compound such as bis(N,N-1-alkylamide-2-dialkylaminoalkane)manganese represented by the general formula Mn(R¹N—Z—NR²₂)₂ disclosed in International Publication No. WO2012/060428.

Here, R, R¹, R², and R³ are alkyl groups represented by —CₙH₂ₙ₊₁ (where n is an integer greater than or equal to 0), and Z is an alkylene group represented by —C—H₂ₙ— (where n is an integer greater than or equal to 0). Among them, (EtCp)₂Mn[═Mn(C₂H₅C₅H₄)₂] may be used in that it is liquid at a room temperature, has a vapor pressure sufficient to supply bubbles, and has high thermal stability.

In addition, a reaction gas other than H₂O may include an oxygen-containing gas, for example, N₂O, NO₂, NO, O₂, O₃, H₂O₂, CO, CO₂, alcohol, aldehyde, carboxylic acid, carboxylic acid anhydride, ester, organic acid ammonium salt, organic acid amine salt, organic acid amide, and organic acid hydrazide. Further, combinations of the plurality of oxygen-containing gases may be used. It is also noted that a reaction gas that is liquid at a room temperature is supplied into the processing chamber after heating and is evaporated into a gas or vapor state.

Also, if the MnOx film 220 is used as the oxide film as described in the embodiment, the oxide film may be formed of another metal oxide or may be formed of material including an oxide of one or more elements selected among Mg, Al, Ca, Ti, V, Cr, Mn, Fe, Co, Ni, Ge, Sr, Y, Zr, Nb, Mo, Rh, Pd, Sn, Ba, Hf, Ta and Ir. Among them, Mn may be used in that it may form a silicate, be solid-soluble with Cu, have a large diffusion coefficient for Cu (have a high diffusion rate in Cu), and be soluble even in acid having no (or weak) oxidizing power.

Then, at Step S110, a hydrogen radical treatment is performed (hydrogen radical treatment process). Specifically, atomic hydrogen is generated by remote plasma, plasma, a heating filament or the like, and the surface of the MnOx film 220 is irradiated with the generated atomic hydrogen. In the embodiment, the atomic hydrogen is generated by the remote plasma generated in the remote plasma generating unit 120 shown in FIGS. 1 and 2, and the surface of the MnOx film 220 on the substrate 210 is irradiated with the generated atomic hydrogen. Here, a heating process may be performed as well, and, for example, the substrate 210 is heated to 300 degrees C. Specifically, in the embodiment, the hydrogen radical treatment is performed under the following conditions of: a gas atmosphere of H₂: 10% and Ar: 90%, a processing pressure of 40 Pa, an input power of 2.5 kW, a substrate heating temperature of 300 degrees C., and a processing time of 60 seconds.

Accordingly, as shown in FIG. 5B, the MnOx film 222 which has been formed on the side surface 215d of the recess 215 and the like is reduced and converted into a Mn film 222a. Further, since the MnOx film 221 formed on the bottom 215c of the via hole 215b is reduced and the reduced Mn is diffused into the first conductive film 212 made of copper and the like, the MnOx film 221 is dissipated. Thus, the first conductive film 212 made of copper and the like is exposed at the bottom 215c of the via hole 215b.

Further, in the hydrogen radical treatment in accordance with the embodiment, the heating temperature of the substrate 210 may be in a range of room temperature to 450 degrees C., may be in a range of 200 degrees C. to 400 degrees C., or may be 300 degrees C. or so. In addition, as for the gas atmosphere, the concentration of H₂ in Ar may be in a range of 1 to 20%, or may be in a range of 3 to 15%. Further, the gas atmosphere may be formed of H₂: 10% and Ar: 90%. Further, the processing pressure may be in a range of 10 to 500 Pa, may be in a range of 20 to 100 Pa, or may be 40 Pa. The input power may be in a range of 1 to 5 kW, may be in a range of 1.5 to 3 kW, or may be 2.5 kW. Further, the processing time may be in a range of 5 to 300 seconds, may be in a range of 10 to 100 seconds, or may be 60 seconds. Further, a degassing process (heat treatment process) may be performed between the formation of the MnOx film 220 at Step S108 and the hydrogen radical treatment at Step S110.

At Step S112, an annealing process is performed in an oxidizing atmosphere (annealing process). Specifically, in the embodiment, the annealing process is performed under the following conditions of: an atmosphere having a small amount of an oxygen-containing gas added to an inert gas such as helium (He), argon (Ar), neon (Ne), nitrogen (N₂), for example, a gas atmosphere having O₂ of 10 ppb to 3 vol % added to Ar, a processing pressure of 13 to 2670 Pa, a processing time of 30 to 1800 seconds, and a substrate heating temperature of 200 to 500 degrees C. or 250 to 350 degrees C. Here, as an oxygen-containing gas other than O₂, for example, H₂O, N₂O, NO₂, NO, O₃, H₂O₂, CO or CO₂ may be used.

Further, when the insulating film 214 and the like are degassed of the oxygen-containing gas such as H₂O by heating the wafer, even if the annealing is performed without supplying an oxygen-containing gas from the outside of the wafer, it is possible to obtain the same effect as when the annealing is performed with the oxygen-containing gas supplied from the outside. When the insulating film and the like are degassed of the oxygen-containing gas by heating the wafer, the annealing may be performed while an inert gas is supplied. In other words, an oxygen-containing gas may be supplied into the wafer processing space from the gas supply system of the processing apparatus, or the components contained in the underlying layer may be removed from the underlying layer and used as the oxygen-containing gas.

It has been described above that the MnOx film 222 formed on the side surface 215d of the recess 215 and the like is entirely reduced by the hydrogen radical treatment at Step S110 and converted into the Mn film 222a. However, depending on the conditions of the hydrogen radical treatment or a film thickness or film quality of the MnOx film 222, there are occasions in which the MnOx film 222 is not entirely reduced and converted into the Mn film 222a. For example, there may be a case where only the MnOx film 222 on the top layer side which is exposed and is not in contact with the insulating film 214 is reduced by the hydrogen radical treatment and converted into the Mn film 222a, while the MnOx film 222 on the bottom layer side which is in contact with the insulating film 214 is not influenced by the reduction action of the hydrogen radical and reacts with the silicon oxide in the insulating film 214 by the heat in the hydrogen radical treatment to form the Mn silicate (MnSixOy) film 222b. In such a case, the formation of Mn silicate is already completed, and the Mn silicate film 222b is finally formed between the insulating film 214 and the second conductive film 230. Thus, the oxidizing atmosphere annealing process at Step S112 may be omitted.

Accordingly, as shown in FIG. 5C, the reduced Mn film 222a which has been formed on the side surface 215d of the recess 215 and the like reacts with the silicon oxide of the insulating film 214 which defines the side surface 215d of the recess 215 and the like, thereby forming the Mn silicate (MnSixOy) film 222b.

In addition, the reaction in which the Mn film 222a is converted into a silicate and becomes the Mn silicate film 222b will be described in detail based on the following description. Specifically, the mechanism that the Mn film 222a reacts with the SiO₂ component contained in the underlying layer and is converted into a silicate to become the Mn silicate film 222b by annealing the wafer W in the oxidizing atmosphere will be described with reference to chemical reaction formulas.

A chemical reaction formula of metal manganese (Mn) and a silicon dioxide (SiO₂) is shown below. In addition, respective chemical reaction formulas show an equilibrium state at 300K. Further, the heat quantity of the right side means a heat quantity (kJ) per mol of manganese (Mn) and indicates the Gibbs free energy change amount (hereinafter, referred to as Gr change amount (ΔGr)). In this regard, the Gibbs free energy tends to voluntarily decrease. Thus, it is known that a chemical reaction having a negative Gr change amount occurs voluntarily but a chemical reaction having a positive Gr change amount does not occur voluntarily. A commercial thermodynamic database was used in the following thermodynamic calculation.

Mn+SiO₂→MnSiO₃ (A)

The chemical reaction formula (A) has the left side and the right side unbalanced in the amount of oxygen and thus is not established as a reaction formula. Therefore, it can be appreciated that a reaction cannot proceed from the left side to the right side, in other words, there is no possibility of conversion into a silicate. From the foregoing, since Mn is not converted into a silicate by merely performing a heat treatment, Mn remains.

Next, when oxygen (O₂) is introduced, a chemical reaction formula of Mn and SiO₂ is shown below:

2Mn+2SiO₂+O₂→2MnSiO₃−380(ΔGr(kJ/Mn-mol)) (B)

From the chemical reaction formula (B), in the case of Mn, as oxygen is supplied, a reaction can proceed from the left side to the right side, in other words, there is a possibility of conversion into a silicate. From the foregoing, due to the introduction of oxygen, Mn may be converted into a silicate and become MnSixOy. In addition, it is confirmed by thermodynamic calculation that the reaction of forming a silicate may proceed with H₂O or CO₂ in addition to O_{2.}

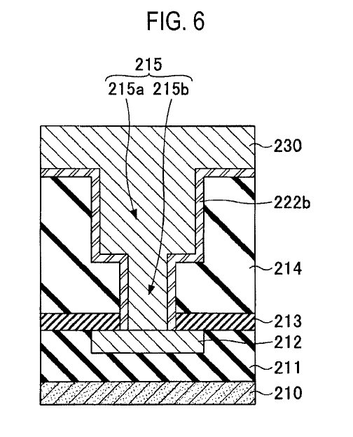

At Step S114, the second conductive film 230 is formed (second conductive film forming process). The second conductive film is typically a metal film such as Cu. Specifically, as illustrated in FIG. 6, the second conductive film 230 such as Cu is formed by any one method of CVD, ALD, PVD, electroplating, electroless plating, and supercritical CO₂. Further, the second conductive film 230 may be formed by a combination of the above-described methods. In the present embodiment, the second conductive film 230 is formed by, first of all, forming a thin Cu film (seed Cu film) by sputtering, and then depositing Cu thereon by electroplating.

Thereafter, as required, a planarizing process may be performed by CMP (Chemical Mechanical Polishing) or the like, thereby removing the second conductive film 230 and the Mn silicate film 222b exposed from the recess 215. By repeating the above-described processes, a required multilayer wiring structure can be formed, and a semiconductor device having a multilayer wiring structure can be manufactured.

In the above processes, the formation of the MnOx film 220 at Step S108, the hydrogen radical treatment at Step S110 and the oxidizing atmosphere annealing process at Step S112 may be performed in the same chamber (processing apparatus) or in different chambers (processing apparatuses), respectively. Further, from a safety standpoint, the hydrogen radical treatment at Step S110 and the oxidizing atmosphere annealing process at Step S112 may be performed in different chambers (processing apparatuses), respectively. When the hydrogen radical treatment at Step S110 and the oxidizing atmosphere annealing process at Step S112 are performed in the same chamber (processing apparatus), H₂O or CO₂ may be used as the oxygen-containing gas used in the oxidizing atmosphere annealing process in light of the reactivity with hydrogen. In order to supply the oxygen-containing gas, the oxygen-containing gas may be supplied into the wafer processing space from the gas supply system of the processing apparatus, or the components contained in the underlying layer may be removed from the underlying layer to be used as the oxygen-containing gas.

According to the manufacturing method of the present embodiment, since the Mn silicate film 222b is formed between the insulating film 214 and the second conductive film 230, it is possible to prevent Cu and the like contained in the second conductive film 230 from being diffused into the insulating film 214 and also prevent O₂ or H₂O contained in the insulating film 214 from being diffused into the second conductive film 230. Further, since the second conductive film 230 is in contact with copper and the like constituting the first conductive film 212, it is possible to obtain sufficient conductivity and thus suppress the occurrence of poor conductivity. Thus, it is possible to miniaturize a multilayer Cu wiring and obtain a miniaturized semiconductor device having a high speed. As a consequence, a compact-sized electronic device having a high speed and a high reliability can be obtained.

### Second Embodiment

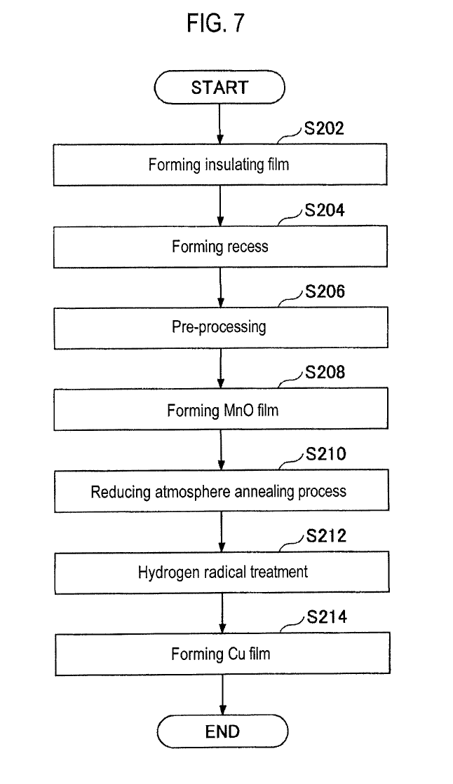

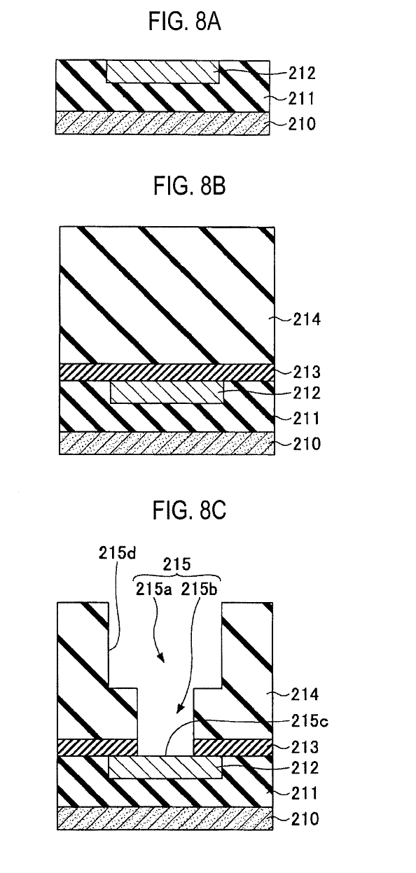

Next, with reference to FIGS. 7 to 10, a second embodiment will be described. A method for manufacturing a semiconductor device of the embodiment is to manufacture a semiconductor device having a multilayer wiring structure and to form an interlayer wiring structure. Thus, description of a semiconductor device, which has already been formed, and a manufacturing method therefor is omitted. In addition, the present embodiment may employ the semiconductor device manufacturing apparatus in accordance with the first embodiment.

The present embodiment is different from the first embodiment in that a MnSiO₃ is formed by reducing atmosphere annealing using a reducing gas such as hydrogen, CO, amine or its analogues (NR¹R²R³), hydrazine or its analogues (N₂R⁴R⁵R⁶R⁷) (wherein R¹ to R⁷ are hydrogen (H) or hydrocarbon) or inert gas annealing using an inert gas, instead of the oxidizing atmosphere annealing.

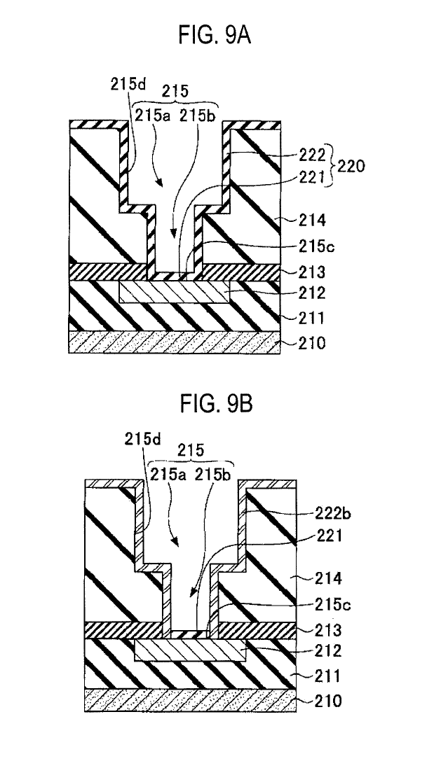

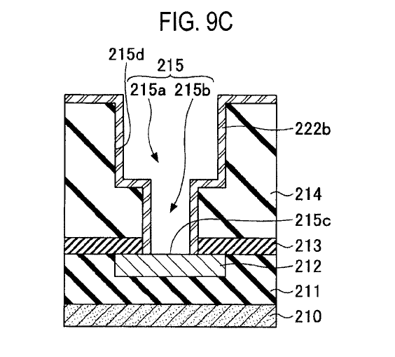

First, by the same processing sequences (Steps S202 to 208) as Steps S102 to 108 (FIG. 3) in the first embodiment, the configuration shown in FIG. 9A is prepared. The same various materials as those described in the first embodiment may be used.

Next, at Step S210, an annealing process using an inert gas or a reducing gas is performed (annealing process). Specifically, in the embodiment, the reducing atmosphere annealing process is performed in an atmosphere having a reducing gas such as hydrogen, CO, amine or its analogues (NR¹R²R³), or hydrazine or its analogues (N₂R⁴R⁵R⁶R⁷) added to an inert gas such as helium (He), argon (Ar), neon (Ne), or nitrogen (N₂). Here, R¹ to R⁷ are hydrogen (H) or hydrocarbon. An analogue of amine (NH₃) may include, for example, methylamine (CH₃NH₂), ethylamine (C₂H₅NH₂), dimethylamine ((CH₃)₂NH), trimethylamine ((CH₃)₃N) and the like. An analogue of hydrazine (N₂H₄) may include, for example, methylhydrazine (CH₃NNH₃), dimethylhydrazine ((CH₃)₂NNH₂), and trimethylhydrazine ((CH₃)₃NNH).

For example, when hydrogen is used as the reducing gas, the annealing process is performed under the following conditions of: a gas atmosphere of H₂: 3% and Ar: 97%, a processing pressure of 13 to 2670 Pa, a processing time of 30 to 1800 seconds, and a substrate heating temperature of 200 to 450 degrees C. or 250 to 350 degrees C.

Further, for convenience, the reducing atmosphere annealing process is illustrated in the figures, but an inert gas annealing process may be performed instead of the reducing atmosphere annealing process when MnOx is formed of only MnO.

Accordingly, as shown in FIG. 9B, the MnOx film 222 formed on the side surface 215d of the recess 215 and the like reacts with the silicon oxide of the insulating film 214 which defines the side surface 215d of the recess 215 and the like, thereby forming the Mn silicate (MnSixOy) film 222b. Further, the MnOx film 221 formed on the bottom 215c of the via hole 215b is formed on the first conductive film 212 such as Cu, and thus, is not converted into a silicate and not changed from the state of the MnOx film 221. Further, very little of the MnOx film 222 formed on the diffusion preventing film 213 is converted into a silicate, and mostly remains as a state of MnOx, which does not matter because the diffusion preventing film 213 includes SiCN and the like and has a diffusion prevention function.

Next, the reaction in which the MnOx film 222 is converted into a silicate and becomes the Mn silicate film 222b will be described in detail based on the following description. Specifically, the mechanism that, the MnOx film 222 reacts with the SiO₂ component contained in the underlying layer and is converted into a silicate and becomes the Mn silicate film 222b by performing an annealing process in the reducing atmosphere will be described with reference to chemical reaction formulas.

Chemical reaction formulas of a manganese oxide (MnO and Mn₂O₃) and a silicon dioxide (SiO₂) are shown below. In addition, the respective chemical reaction formulas show an equilibrium state at 300K. Further, the heat quantity of the right side means a heat quantity (kJ) per mol of manganese (Mn) and indicates the Gibbs free energy change amount (hereinafter, referred to as Gr change amount (ΔGr)) by a two-digit effective number. In this regard, the Gibbs free energy tends to voluntarily decrease. Thus, it is known that a chemical reaction having a negative Gr change amount occurs voluntarily but a chemical reaction having a positive Gr change amount does not occur voluntarily. A commercial thermodynamic database was used in the following thermodynamic calculation.

MnO+SiO₂→MnSiO₃−21(ΔGr(kJ/Mn-mol)) (1)

2Mn₂O₃+4SiO₂→4MnSiO₃+O₂+57(ΔGr(kJ/Mn-mol)) (2)

2Mn₂O₃+2SiO₂→2Mn₂SiO₄+O₂+53(ΔGr(kJ/Mn-mol)) (3)

From the chemical reaction formula (1), in the case of MnO, a reaction can proceed from the left side to the right side, in other words, there is a possibility of conversion into a silicate. In addition, it can be appreciated from the chemical reaction formulas (2) and (3) that a reaction cannot proceed from the left side to the right side, in other words, there is no possibility of conversion into a silicate. From the foregoing, Mn₂O₃ is not converted into a silicate by merely performing a heat treatment and, therefore, Mn₂O₃ remains.

Next, when hydrogen (H) is introduced, chemical reaction formulas of Mn₂O₃ and SiO₂ are shown below:

Mn₂O₃+2SiO₂+H₂→2MnSiO₃+H₂O−58(ΔGr(kJ/Mn-mol)) (4)

Mn₂O₃+SiO₂+H₂→Mn₂SiO₄+H₂O−62(ΔGr(kJ/Mn-mol)) (5)

From the chemical reaction formulas (4) and (5), when hydrogen (H) is introduced, a reaction can proceed from the left side to the right side even if Mn₂O₃ is used, i.e., there is a possibility of conversion into a silicate. From the foregoing, due to the introduction of hydrogen, Mn₂O₃ is converted into a silicate and can become MnSixOy.

Next, chemical reaction formulas of Mn₂O₃ are shown below:

2Mn₂O₃→4MnO+O₂+78(ΔGr(kJ/Mn-mol)) (6)

Mn₂O₃+H₂→2MnO+H₂O−37(ΔGr(kJ/Mn-mol)) (7)

From the chemical reaction formula (6), when no hydrogen in introduced, Mn₂O₃ cannot become MnO. As shown in the chemical reaction formulas (2) and (3), Mn₂O₃ cannot be converted into a silicate without hydrogen. Therefore, when no hydrogen is introduced, Mn₂O₃ cannot be converted into a silicate and cannot become a manganese silicate (MnSixOy).

On the contrary, from the chemical reaction formula (7), due to the introduction of hydrogen, Mn₂O₃ may become MnO. As shown in the chemical reaction formula (1), since MnO can be converted into a silicate and become a manganese silicate (MnSixOy), Mn₂O₃ can be converted into a silicate and become a manganese silicate (MnSixOy) by the introduction of hydrogen.

Subsequently, when CO is introduced as the reducing gas, a chemical reaction formula is shown below:

Mn₂O₃+CO→2MnO+CO₂−51(ΔGr(kJ/Mn-mol)) (a1)

Also, as shown in the chemical reaction formula (1), MnO can be converted into a silicate by annealing.

Mn₂O₃+2SiO₂+CO→2MnSiO₃+CO₂−72(ΔGr(kJ/Mn-mol)) (a2)

Mn₂O₃+SiO₂+CO→Mn₂SiO₄+CO₂−76(ΔGr(kJ/Mn-mol)) (a3)

Subsequently, when NH₃ is introduced as the reducing gas, a chemical reaction formula is shown below:

Mn₂O₃+0.5NH₃→2MnO+0.25N₂O+0.75H₂O+9.0(ΔGr(kJ/Mn-mol)) (b1)

Here, if the temperature is 500K or more, ΔGr becomes negative. Also, as shown in the chemical reaction formula (1), MnO may be converted into a silicate by annealing.

Mn₂O₃+2SiO₂+0.5NH₃→2MnSiO₃+0.25N₂O+0.75H₂O−12(ΔGr(kJ/Mn-mol)) (b2)

Mn₂O₃+SiO₂+0.5NH₃→Mn₂SiO₄+0.25N₂O+0.75H₂O−16(ΔGr(kJ/Mn-mol)) (b3)

Subsequently, when N₂H₄ is introduced as the reducing gas, the chemical reaction formulas are shown below:

Mn₂O₃+2SiO₂+0.33N₂H₄→2MnSiO₃+0.33N₂O+0.67H₂O−29(ΔGr(kJ/Mn-mol)) (c1)

Mn₂O₃+SiO₂+0.33N₂H₄→Mn₂SiO₄+0.33N₂O+0.67H₂O−33(ΔGr(kJ/Mn-mol)) (c2)

As described above, it can be seen from the chemical reaction formulas (a2), (a3), (b2), (b3), (c1) and (c2) that even when CO, NH₃ or N₂H₄ is introduced as the reducing gas, Mn₂O₃ can be converted into a silicate and become a Mn silicate (MnSixOy).

Then, at Step S212, a hydrogen radical treatment is performed (hydrogen radical treatment process). The sequence of the hydrogen radical treatment is the same as the first embodiment, and thus, the details thereof will be omitted.

Accordingly, as shown in FIG. 9C, since the MnOx film 221 that has been formed on the bottom 215c of the via hole 215b is reduced and the reduced Mn is diffused into the first conductive film 212 made of Cu or the like, the MnOx film 221 is dissipated. Thus, the first conductive film 212 made of copper and the like is exposed at the bottom 215c of the via hole 215b. Here, since the Mn silicate film 222b formed on the side surface 215d of the recess 215 and the like is relatively stable as a substance, it is considered to have very little change.

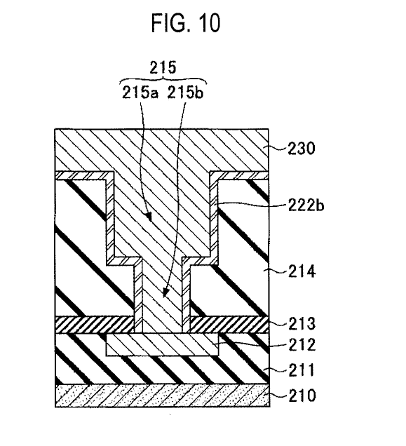

Then, at Step S214, as shown in FIG. 10, the second conductive film 230 such as Cu is formed (second conductive film forming process). The sequence of the formation of the second conductive film is the same as the first embodiment, and thus, the details thereof will be omitted.

Thereafter, as required, a planarizing process may be performed by CMP or the like, thereby removing the second conductive film 230 and the Mn silicate film 222b exposed from the recess 215. By repeating the above-described processes, a required multilayer wiring structure can be formed, and a semiconductor device having a multilayer wiring structure can be manufactured.

In the above processes, the formation of the MnOx film 220 at Step S208, the inert gas annealing process or the reducing atmosphere annealing process at Step S210, and the hydrogen radical treatment at Step S212 may be performed in the same chamber (processing apparatus), or in different chambers (processing apparatuses), respectively. In addition, the MnOx film 220 is formed at Step S208 while hydrogen is introduced, so that the film forming process at Step S208 and the annealing process at Step S210 may be simultaneously performed.

According to the manufacturing method of the present embodiment, since the Mn silicate film 222b is formed between the insulating film 214 and the second conductive film 230, it is possible to prevent Cu and the like contained in the second conductive film 230 from being diffused into the insulating film 214 and also prevent O₂ or H₂O contained in the insulating film 214 from being diffused into the second conductive film 230. Further, since the second conductive film 230 is in contact with copper and the like constituting the first conductive film 212, it is possible to obtain sufficient conductivity and thus suppress the occurrence of poor conductivity. Accordingly, it is possible to miniaturize a multilayer Cu wiring and obtain a miniaturized semiconductor device having a high speed. As a consequence, a compact-sized electronic device having a high speed and a high reliability can be obtained. In addition, descriptions other than the foregoing are the same as the first embodiment.

### Third Embodiment

The present embodiment is different from the first embodiment in that a third conductive film (Ru film), which functions as an adhesion layer to improve adhesion between the Mn silicate (MnSixOy) film 222b and the second conductive film 230, is formed therebetween. Ru (002) has a lattice constant of 2.14 angstroms, and Cu (111) has a lattice constant of 2.09 angstroms. Since Ru and Cu are close to each other in the lattice constant and have good wettability to each other, high adhesion and good fillability of the second conductive film 230 such as Cu into the recess 215 can be expected.

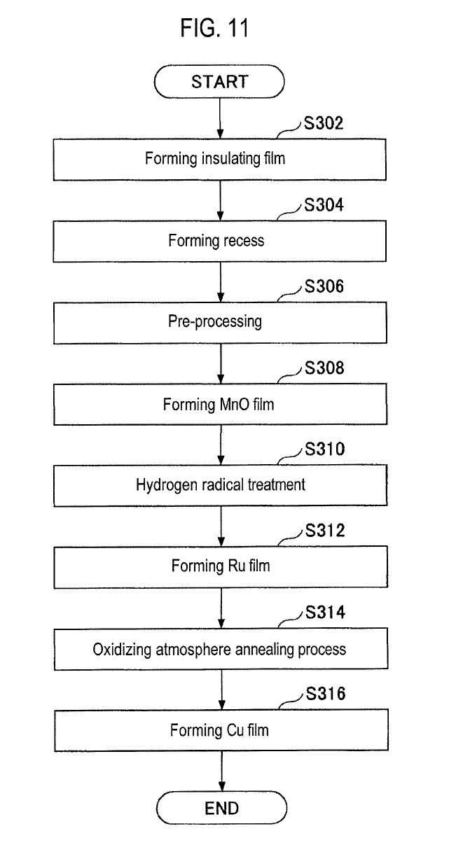

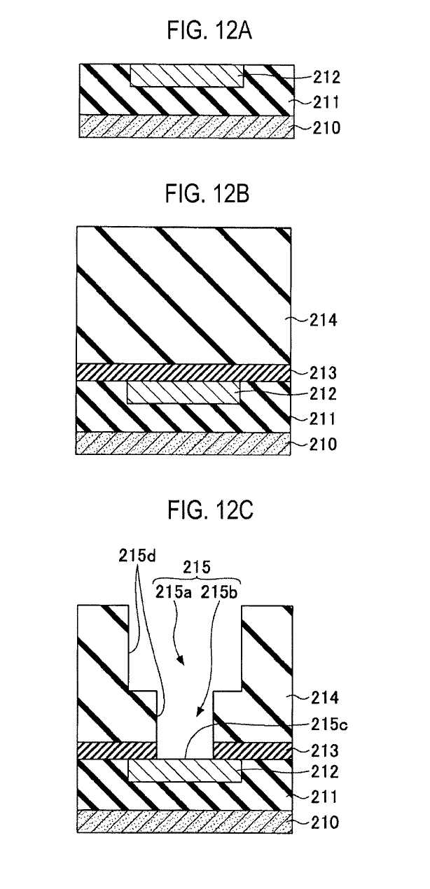

Next, with reference to FIGS. 11 to 14b, a third embodiment will be described. A method for manufacturing a semiconductor device of the embodiment is to manufacture a semiconductor device having a multilayer wiring structure and to form an interlayer wiring structure. Thus, description of a semiconductor device, which has already been formed, and a method therefor is omitted. In addition, the present embodiment may employ the semiconductor device manufacturing apparatus of the first embodiment.

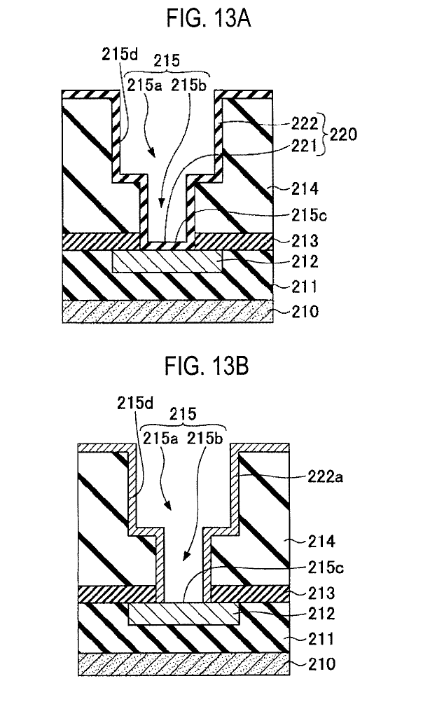

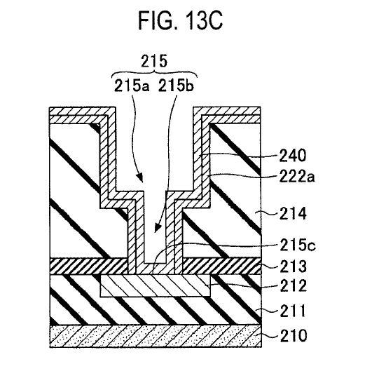

First, through the same processing sequences (Steps S302 to 310) as Steps S102 to S110 (FIG. 3) in the first embodiment, the configuration shown in FIG. 13B is prepared. The same various materials as those described in the first embodiment may be used.

Then, at Step S312, a third conductive film (Ru film) 240 is formed (third conductive film forming process). Specifically, as shown in FIG. 13C, using an organic metal raw material containing Ru (for example, Ru carbonyl or the like), the third conductive film 240 is formed by CVD by heating the substrate 210 at about 200 degrees C. The third conductive film 240 is a metal material and is formed on the inner surface of the recess 215 including the bottom 215c of the via hole 215b. That is, the third conductive film 240 is formed on the exposed surface of the first conductive film 212 and the Mn film 222a in the recess 215. Since the Mn film 222a is not formed on the exposed surface of the first conductive film 212 in the bottom 215c of the via hole 215b as described above, the third conductive film 240 is formed on the surface of copper and the like constituting the first conductive film 212.

Next, at Step S314, an annealing process is performed in an oxidizing atmosphere (annealing process). Specifically, in the embodiment, the annealing process is performed under the following conditions of: an atmosphere having a small amount of an oxygen-containing gas added to an inert gas such as helium (He), argon (Ar), neon (Ne), nitrogen (N₂), for example, a gas atmosphere having O₂ of 10 ppb to 3 vol % added to Ar, a processing pressure of 13 to 2670 Pa, a processing time of 30 to 1800 seconds, and a substrate heating temperature of 200 to 500 degrees C. or 250 to 350 degrees C. Here, as an oxygen-containing gas other than O₂, for example, H₂O, N₂O, NO₂, NO, O₃, H₂O₂, CO, or CO₂ may be used.

Further, when the insulating film 214 and the like are degassed of the oxygen-containing gas such as H₂O by heating the wafer, even if the annealing is performed without supplying an oxygen-containing gas from the outside of the wafer, it is possible to obtain the same effect as when the annealing is performed with the oxygen-containing gas supplied from the outside. When the insulating film and the like are degassed of the oxygen-containing gas by heating the wafer, the annealing may be performed while an inert gas is supplied. In other words, an oxygen-containing gas may be supplied into the wafer processing space from the gas supply system of the processing apparatus, or the components contained in the underlying layer may be removed therefrom and used as the oxygen-containing gas.

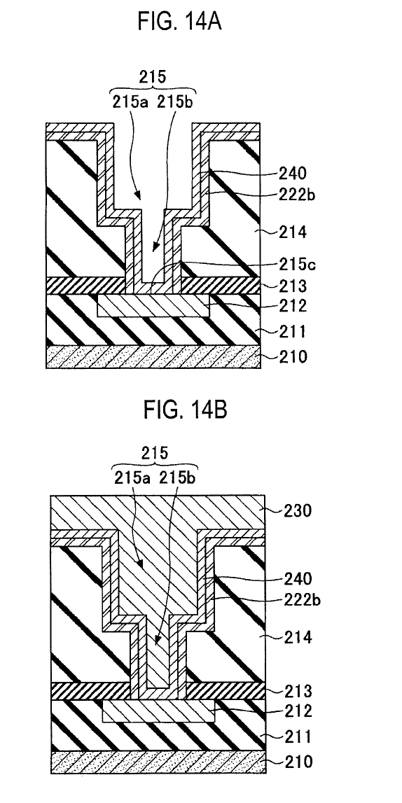

Accordingly, as shown in FIG. 14A, the reduced Mn film 222a which has been formed on the side surface 215d of the recess 215 and the like reacts with the silicon oxide of the insulating film 214 which defines the side surface 215d of the recess 215 and the like, thereby forming the Mn silicate (MnSixOy) film 222b.

Further, in the embodiment, a predetermined level of vacuum or a predetermined oxygen partial pressure may be maintained between the hydrogen radical treatment at Step S310 and the formation of the third conductive film 240 at Step S312. For example, the vacuum may be maintained at 1×10⁻⁴ Pa or less. Accordingly, the hydrogen radical treatment at Step S310 and the formation of the third conductive film 240 at Step S312 may be performed in the same chamber as shown in FIG. 2. Alternatively, as shown in FIG. 1, the chamber in which the hydrogen radical treatment is performed and the chamber in which the formation of the third conductive film 240 is performed are connected by the common transfer chamber 121 capable of maintaining a predetermined level of vacuum, and the wafer W may be transferred through the common transfer chamber 121.

Further, between the hydrogen radical treatment at Step S310 and the formation of the third conductive film 240 at Step S312, there may be a cooling process for cooling the substrate 210 to a temperature less than or equal to a Ru film forming temperature, for example, to room temperature. The formed third conductive film 240 has a film thickness of 0.5 to 5 nm, and the third conductive film 240 may be formed by ALD, other than CVD. In addition, although the case that the Ru film as the third conductive film 240 is formed has been described in the embodiment, the third conductive film 240 may be made of a metal material, other than Ru, for example, a material containing one or more elements selected among Fe, Co, Ni, Rh, Pd, Os, Ir and Pt. Furthermore, a material containing one or more elements selected among platinum group elements may be used. They have a good adhesion to Cu and are electrically conductive, and thus, have the same function as the seed Cu layer.

At Step S316, as shown in FIG. 14B, the second conductive film 230 such as Cu is formed (second conductive film forming process). The sequence of the formation of the second conductive film is the same as the first embodiment, and thus, the details thereof will be omitted.

Thereafter, as required, a planarizing process may be performed by CMP or the like, thereby removing the second conductive film 230 and the Mn silicate film 222b exposed from the recess 215. By repeating the above-described processes, a required multilayer wiring structure can be formed, and a semiconductor device having a multilayer wiring structure can be manufactured.

In the above processes, the formation of the MnOx film 220 at Step S308 and the hydrogen radical treatment at Step S310 may be performed in the same chamber (processing apparatus) or in different chambers (processing apparatuses) respectively.

According to the manufacturing method of the present embodiment, since the third conductive film 240 and the Mn silicate film 222b is formed between the insulating film 214 and the second conductive film 230, it is possible to prevent Cu and the like contained in the second conductive film 230 from being diffused into the insulating film 214 and also prevent O₂ or H₂O contained in the insulating film 214 from being diffused into the second conductive film 230. Further, since the second conductive film 230 is in contact with the first conductive film 212 via the third conductive film 240 which is a metal material having high conductivity, it is possible to obtain sufficient conductivity and thus suppress the occurrence of poor conductivity. In addition, since the interposition of the third conductive film 240 causes wettability with the second conductive film 230 (Cu) to be improved, it is possible to expect enhanced fillability of the second conductive film 230 (Cu) along with improved adhesion. Accordingly, it is possible to miniaturize a multilayer Cu wiring and obtain a highly miniaturized semiconductor device having a high speed. As a consequence, a compact-sized electronic device having a high speed and a high reliability can be obtained. In addition, descriptions other than the foregoing are the same as the first embodiment. Further, the present embodiment may be applied in the method for manufacturing the semiconductor device in accordance with the second embodiment. In such a case, the film forming process of the third conductive film 240 at Step S312 is interposed between the hydrogen radical treatment process at Step S212 and the film forming process of the Cu film 230 at Step S214.

### Fourth Embodiment

The present embodiment is different from the second embodiment in that the MnOx film 221 formed on the bottom of the recess 215 is selectively removed by wet etching.

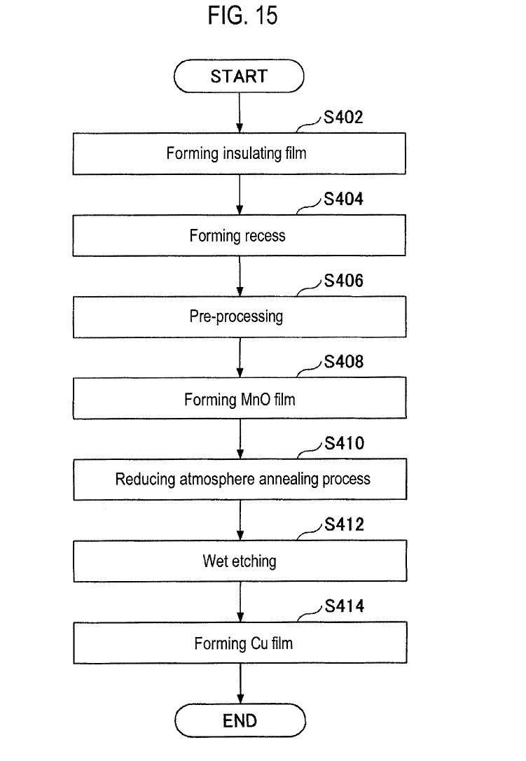

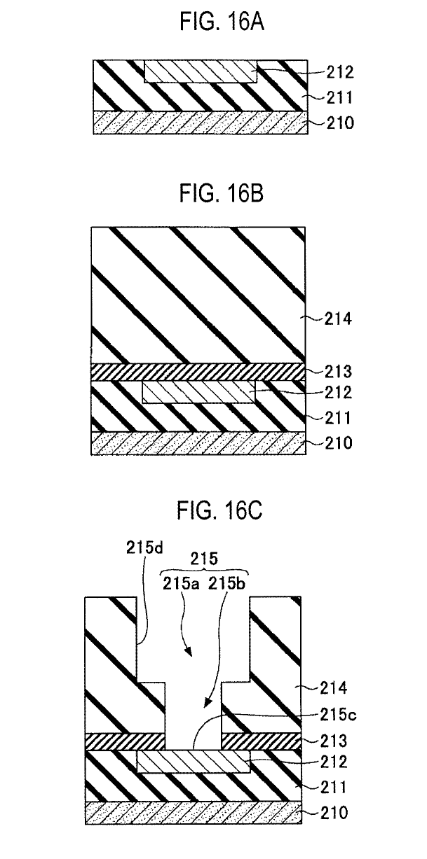

Next, with reference to FIGS. 15 to 18, the fourth embodiment will be described. A method for manufacturing a semiconductor device of the embodiment is to manufacture a semiconductor device having a multilayer wiring structure and to form an interlayer wiring structure. Thus, description of a semiconductor device, which has already been formed, and a method therefor is omitted. In addition, the present embodiment may partially employ the semiconductor device manufacturing apparatus of the first embodiment.

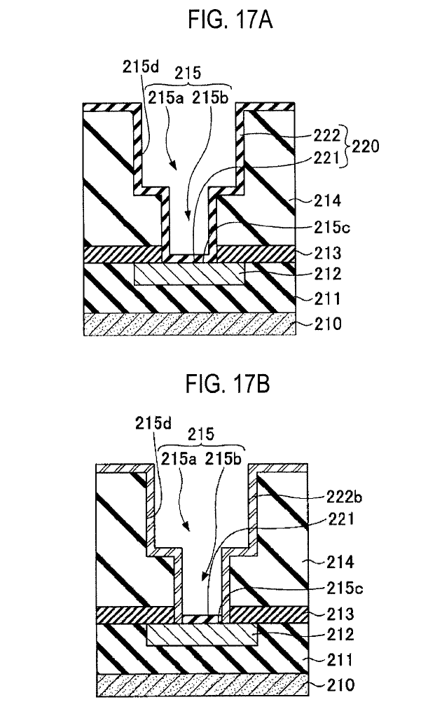

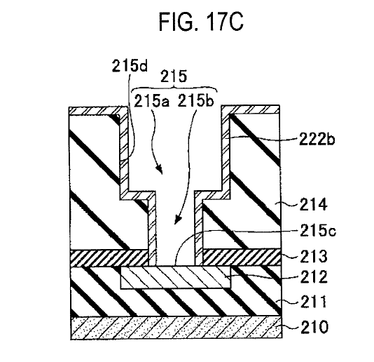

First, by the same processing sequences (Steps S402 to S408) as Steps S102 to S108 (FIG. 3) in the first embodiment, the configuration shown in FIG. 17A is prepared. The same various materials as those described in the first embodiment may be used.

Then, at Step S410, an inert gas or hydrogen-containing gas annealing process or a reducing atmosphere annealing process is performed (inert gas annealing process or reducing atmosphere annealing process). The sequence thereof is the same as the second embodiment (Step S210), and thus, the details thereof will be omitted.

Accordingly, as shown in FIG. 17B, the MnOx film 222 which has been formed on the side surface 215d of the recess 215 and the like reacts with the silicon oxide of the insulating film 214 which defines the side surface 215d of the recess 215 and the like, thereby forming the Mn silicate (MnSixOy) film 222b. Further, the MnOx film 221 formed on the bottom 215c of the via hole 215b is formed on the first conductive film 212 such as Cu, and thus, is not converted into a silicate and not changed from the state of the MnOx film 221. In addition, very little of the MnOx film 222 that has been formed on the diffusion preventing film 213 is converted into a silicate and remains as a state of MnOx, which does not matter because the diffusion preventing film 213 includes SiCN and the like and has a diffusion prevention function.

Then, at Step S412, a wet etching process is performed using hydrochloric acid. Specifically, after the inert gas annealing process or the reducing atmosphere annealing process is performed, immersion in hydrochloric acid is performed, whereby, as shown in FIG. 17C, the MnOx film 221 formed on the first conductive film 212 such as Cu is dissolved and removed by the hydrochloric acid. Here, since the Mn silicate film 222b formed on the side surface 215d of the recess 215 and the like has been converted into a silicate, the Mn silicate film 222b is not penetrated by the hydrochloric acid and thus is not removed.

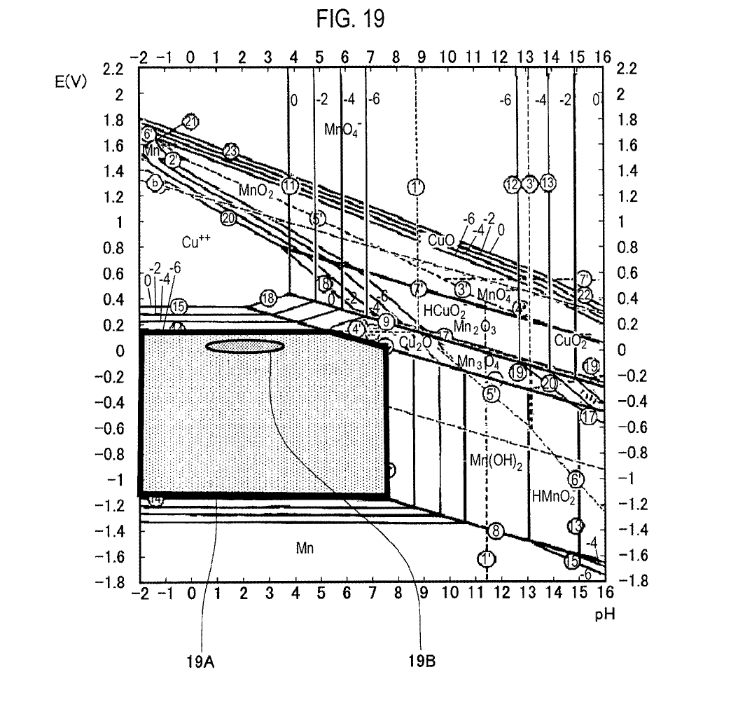

FIG. 19 shows a relationship between a pH value and a potential of a standard hydrogen electrode. As shown in FIG. 19, there is a range 19A in which Mn is melted but Cu is not melted (a range in which Mn is ionized but Cu is not ionized (a range of greater than or equal to about −1.2 V to less than or equal to 0.1 V in the figure)). Further, within this range 19A, a range 19B exists in which Mn is melted but Cu and MnSiO₃ are not melted. In the present embodiment, the wet etching is performed under the conditions in the range 19B (greater than or equal to about −0.1V to less than or equal to 0.1 V). Accordingly, as shown in FIG. 17C, the Mn silicate film 222b formed on the side surface 215d of the recess 215 and the like is not removed, but the MnOx film 221, which is formed on the bottom 215c of the recess 215 that is over the first conductive film 212 such as Cu, may be removed.

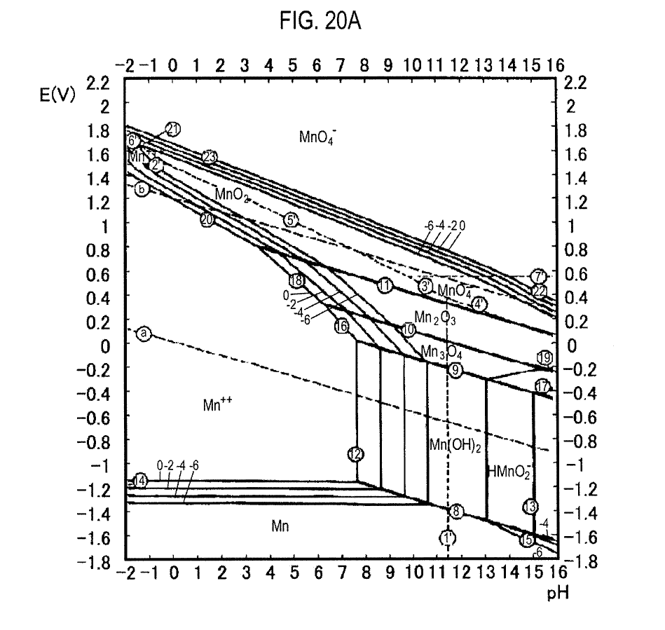

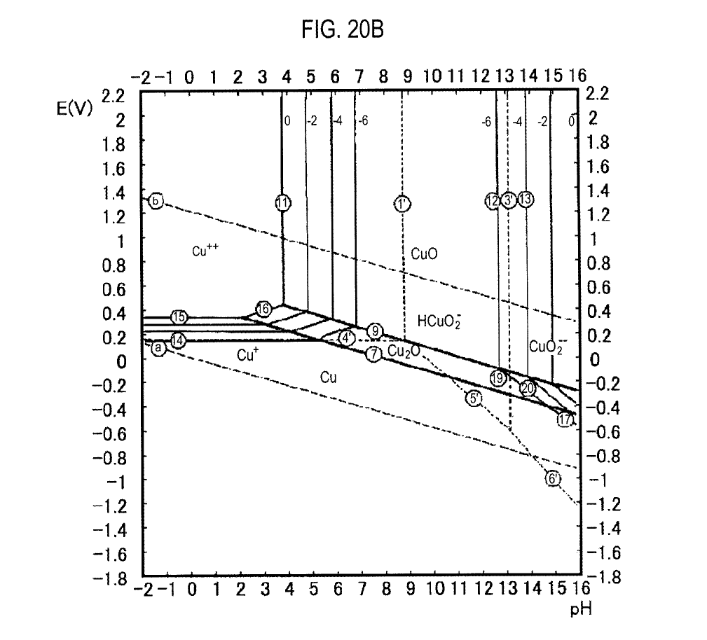

Further, FIG. 19 is to be obtained by overlapping a relationship between a pH value in Mn and a potential of a standard hydrogen electrode as shown in FIG. 20A and a relationship between a pH value in Cu and a potential of a standard hydrogen electrode as shown in FIG. 20B. In FIGS. 19, 20A and 20B, the horizontal axis represents the pH value and the vertical axis represents the potential of the standard hydrogen electrode. In addition, although the case that hydrochloric acid is used has been described in the embodiment, acetic acid, citric acid or the like may be used. Here, acid having no oxidizing power (weak acid) may be selected, and the wet etching using a neutral or acid chemical liquid may be used.

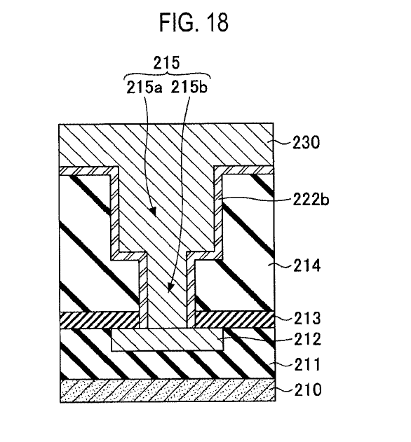

Then, as shown in FIG. 18, at Step S414, the second conductive film 230 such as Cu is formed (second conductive film forming process). The sequence of the formation of the second conductive film is the same as the first embodiment, and thus, the details thereof will be omitted.

Thereafter, as required, a planarizing process may be performed by CMP or the like, thereby removing the second conductive film 230 and the Mn silicate film 222b exposed from the recess 215. By repeating the above-described processes, a required multilayer wiring structure can be formed, and a semiconductor device having a multilayer wiring structure can be manufactured.

In the above processes, the formation of the MnOx film 220 at Step S408 and the inert gas annealing process or the reducing atmosphere annealing process at Step S410 may be performed in the same chamber (processing apparatus), or may be performed in different chambers (processing apparatuses) respectively. In addition, the MnOx film 220 is formed at Step S408 while hydrogen is introduced, so that the film forming process at Step S408 and the annealing process at Step S410 may be simultaneously performed. Also, a chamber (processing apparatus) in which the wet etching is performed is connected to the common transfer chamber 121 to form a cluster tool.

According to the manufacturing method of the present embodiment, since the Mn silicate film 222b is formed between the insulating film 214 and the second conductive film 230, it is possible to prevent Cu and the like contained in the second conductive film 230 from being diffused into the insulating film 214 and also prevent O₂ or H₂O contained in the insulating film 214 from being diffused into the second conductive film 230. Further, since the second conductive film 230 is in contact with copper and the like constituting the first conductive film 212, it is possible to obtain sufficient conductivity and thus suppress the occurrence of poor conductivity. In the embodiment, since the MnOx film 221 formed on the bottom 215c of the recess 215 is previously removed by the wet etching, and thus, Mn is not diffused into the first conductive film 212, it is possible to make wiring resistance even lower. Accordingly, it is possible to miniaturize a multilayer Cu wiring and obtain a highly miniaturized semiconductor device having a high speed. As a consequence, a compact-sized electronic device having a high speed and a high reliability can be obtained. In addition, descriptions other than the foregoing are the same as the first or second embodiment.

### Fifth Embodiment

Without limitation to the formation of the above-described MnOx film, in some cases, the present disclosure may be partially applied to a case where a metal Mn film is formed by a film forming means such as thermal ALD, thermal CVD, plasma ALD, or plasma CVD. For example, a Mn film is formed by heating the substrate 210 to 200 to 400 degrees C., for example, 300 degrees C., and supplying a Mn precursor such as the above-described amideaminoalkane-based manganese compound. Thus, in general, the Mn film is formed on the bottom 215c of the via hole 215b and the side surface 215d of the recess 215 and the like. However, when the native oxide film (CuOx) cannot be completely removed from the Cu surface but remains thereon, in some cases, the reaction of the formed metal Mn and CuOx may cause a MnOx film to be formed on the bottom of the recess at which Cu is exposed. At that time, by the hydrogen radical treatment to irradiate the substrate with atomic hydrogen, the MnOx deposited on Cu may be reduced and simultaneously diffused into Cu (the underlying first conductive film) and dissipated, whereby the MnOx is removed.

### [Modifications]

In addition, while the embodiments of the present disclosure have been described, they are not intended to limit the present disclosure thereto.

For example, an example in which after the oxidizing atmosphere annealing process at Step S112 of FIG. 3 is performed, the formation of the Cu film (second conductive film) at Step S114 has been described in the first embodiment. However, as another example, Mn may also be converted into a silicate and become MnSixOy by forming the Cu film (second conductive film) in the same manner as Step S114 and then performing the oxidizing atmosphere annealing process in the same manner as Step S112. The same is also true of the other embodiments.

In addition, for example, an example in which after the formation of the Ru film (third conductive film) at Step S312 of FIG. 11 is performed, the oxidizing atmosphere annealing process at Step S314 is performed has been described in the third embodiment. However, as another example, after the oxidizing atmosphere annealing process at Step S314 is performed, the formation of the Ru film (third conductive film) at Step S312 may be performed. Also, the oxidizing atmosphere annealing process at Step S314 may be performed after the formation of the Cu film (second conductive film) at Step S316 is performed.

Further, the processes of the respective embodiments may be appropriately combined. For example, in the sequence of the second embodiment, the formation of the Ru film (third conductive film) at Step S312 of FIG. 11 described in the third embodiment may be performed. In such a case, the process of forming the Ru film (the third conductive film 240) at Step S312 is interposed between the hydrogen radical treatment process at Step S212 and the process of forming the Cu film (the second conductive film 230) at Step S214.

The claims of Japanese Patent Application No. 2012-159652, filed Jul. 18, 2012, are prerequisites for the following (Item 1) to (Item 27).

The present disclosure also includes the following (Item 1) to (Item 27).

### (Item 1)

A method for manufacturing a semiconductor device, including:

an oxide film forming process of forming an oxide film made of a metal oxide in an opening (recess) formed in an insulating film, the insulating film being formed on a surface of a substrate;

a hydrogen radical treatment process of irradiating the substrate with atomic hydrogen after the oxide film forming process;

an oxygen annealing process of heating the substrate while oxygen is supplied after the oxide film forming process; and
an electrode forming process of forming an electrode made of metal in the opening after the hydrogen radical treatment process and the oxygen annealing process are performed.

### (Item 2)

A method for manufacturing a semiconductor device, including:

an oxide film forming process of forming an oxide film made of a metal oxide in an opening formed in an insulating film, the insulating film being formed on a surface of a substrate;

a hydrogen radical treatment process of irradiating the substrate with atomic hydrogen after the oxide film forming process;

an electrode forming process of forming an electrode made of metal in the opening after the oxide film forming process; and

an oxygen annealing process of heating the substrate while oxygen is supplied after the electrode forming process.

### (Item 3)

The method for manufacturing the semiconductor device of Item 1 or 2, wherein the oxygen annealing process is performed after the hydrogen radical treatment process.

### (Item 4)

A method for manufacturing a semiconductor device, including:

an oxide film forming process of forming an oxide film made of a metal oxide in an opening formed in an insulating film, the insulating film being formed on a surface of a substrate;

a hydrogen annealing process of heating the substrate while hydrogen is supplied after the oxide film forming process;

a hydrogen radical treatment process of irradiating the substrate with atomic hydrogen after the hydrogen annealing process; and

an electrode forming process of forming an electrode made of metal in the opening after the hydrogen annealing process and the hydrogen radical treatment process are performed.

### (Item 5)

The method for manufacturing the semiconductor device of any one of Items 1 to 4, wherein the hydrogen radical treatment process is performed while the substrate is heated.

### (Item 6)

The method for manufacturing the semiconductor device of any one of Items 1 to 5, wherein the atomic hydrogen is generated by remote plasma.

### (Item 7)

A method for manufacturing a semiconductor device, including:

an oxide film forming process of forming an oxide film made of a metal oxide in an opening formed in an insulating film, the insulating film being formed on a surface of a substrate;

a hydrogen annealing process of heating the substrate while hydrogen is supplied after the oxide film forming process;

a wet etching process of removing the oxide film from a bottom of the opening by wet etching after the hydrogen annealing process; and

an electrode forming process of forming an electrode made of metal in the opening after the wet etching process is performed.

### (Item 8)

The method for manufacturing the semiconductor device of Item 7, wherein etching liquid including any one of hydrochloric acid, acetic acid and citric acid is used for the wet etching.

### (Item 9)

The method for manufacturing the semiconductor device of Item 7, wherein the wet etching is performed using a neutral or acid chemical liquid.

### (Item 10)

The method for manufacturing the semiconductor device of Item 9, wherein the chemical liquid has an oxidation-reduction potential of less than or equal to 0.1 V.

### (Item 11)

The method for manufacturing the semiconductor device of Item 9, wherein the chemical liquid has an oxidation-reduction potential of greater than or equal to −1.2 V and less than or equal to 0.1 V.

### (Item 12)

The method for manufacturing the semiconductor device of any one of Items 1 to 11, wherein the oxide film is formed by ALD.

### (Item 13)

The method for manufacturing the semiconductor device of any one of Items 1 to 12, wherein the oxide film is formed of material including an oxide of one or more elements selected from a group including Mg, Al, Ca, Ti, V, Cr, Mn, Fe, Co, Ni, Ge, Sr, Y, Zr, Nb, Mo, Rh, Pd, Sn, Ba, Hf, Ta and Ir.

### (Item 14)

The method for manufacturing the semiconductor device of any one of Items 1 to 13, wherein the oxide film includes an oxide of Mn.

### (Item 15)

The method for manufacturing the semiconductor device of any one of Items 1 to 14, wherein a metal film (conductive film) forming process is performed after the hydrogen radical treatment process and the hydrogen annealing process or the oxygen annealing process are performed, and the electrode forming process is performed after the metal film forming process is performed, the metal film being formed of material including one or more elements selected from a group including Fe, Co, Ni, Ru, Rh, Pd, Os, Ir and Pt.

### (Item 16)

The method for manufacturing the semiconductor device of any one of Items 4, 7 and 15, wherein, instead of the hydrogen annealing process, an inert gas annealing process of heating the substrate while an inert gas is supplied is performed.

### (Item 17)

The method for manufacturing the semiconductor device of any one of Items 1 to 16, wherein, instead of the oxide film forming process, a film including Mn is formed, the film including Mn being formed by thermal CVD or plasma CVD.

### (Item 18)

The method for manufacturing the semiconductor device of any one of Items 1 to 17, wherein the electrode is formed of copper or material including copper.

### (Item 19)

The method for manufacturing the semiconductor device of any one of Items 1 to 18, wherein the electrode is formed by one or more methods selected among thermal CVD, thermal ALD, plasma CVD, plasma ALD, PVD, electroplating, electroless plating, and supercritical CO_{2.}

### (Item 20)

A semiconductor device having a film structure formed by the method for manufacturing the semiconductor device of any one of Items 1 to 19.

### (Item 21)

A semiconductor device manufacturing apparatus having one or more chambers,

wherein an oxide film made of a metal oxide is formed in any one of the chambers,

wherein a hydrogen radical treatment process of performing an irradiation using atomic hydrogen is performed in any one of the chambers,

wherein an annealing process of performing a heating operation while hydrogen or oxygen or an inert gas is supplied is performed in any one of the chambers, and

wherein an electrode made of metal is formed in any one of the chambers.

### (Item 22)

The semiconductor device manufacturing apparatus of Item 21, wherein the oxide film is formed by ALD.

### (Item 23)

The semiconductor device manufacturing apparatus of Item 21 or 22, wherein the oxide includes an oxide of Mn.

### (Item 24)

A semiconductor device manufacturing apparatus having one or more chambers,

wherein a metal film is formed by thermal CVD or plasma CVD in any one of the chambers;

wherein a hydrogen radical treatment process of performing an irradiation using atomic hydrogen is performed in any one of the chambers;

wherein an annealing process of performing a heating operation while hydrogen or oxygen or an inert gas is supplied is performed in any one of the chambers; and

wherein an electrode made of metal is formed in any one of the chambers.

### (Item 25)

The semiconductor device manufacturing apparatus of Item 24, wherein the metal film is a film including Mn.

### (Item 26)

The semiconductor device manufacturing apparatus of Item 21 or 25, wherein the hydrogen radical treatment process and the annealing process of performing a heating operation while the hydrogen or oxygen or the inert gas is supplied are performed in the same chamber.

### (Item 27)

The semiconductor device manufacturing apparatus of Item 21 or 26, wherein the formation of the oxide film, the hydrogen radical treatment process, and the annealing process of performing a heating operation while the hydrogen or oxygen or the inert gas is supplied are performed in the same chamber.

According to a method for manufacturing a semiconductor device of the present disclosure, the semiconductor device is formed in such a manner that a recess such as a trench is formed in an insulating film, a metal oxide film such as a MnOx film is formed in the recess, and a conductive film such as Cu is formed thereon. Therefore, sufficient conductivity, desired properties, and high production yield can be obtained, and reliability can be improved.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for manufacturing a semiconductor device, comprising:
forming an insulating film on a substrate where a first conductive film is formed;
forming a recess in the insulating film such that the first conductive film is exposed in a portion of the recess;
forming a metal oxide film to cover the insulating film and the first conductive film after forming a recess;
performing a hydrogen radical treatment of irradiating the substrate with atomic hydrogen after forming a metal oxide film; and
forming a second conductive film in the recess.

2. A method for manufacturing a semiconductor device, comprising:
forming an insulating film on a substrate where a first conductive film is formed;
forming a recess in the insulating film such that the first conductive film is exposed in a portion of the recess;
forming a metal oxide film to cover the insulating film and the first conductive film after forming a recess;
performing an annealing process of heating the substrate in a reducing atmosphere or an inert gas atmosphere after forming a metal oxide film;
performing a hydrogen radical treatment to irradiate the substrate with atomic hydrogen after performing an annealing process; and
forming a second conductive film in the recess after performing a hydrogen radical treatment.

3. A method for manufacturing a semiconductor device, comprising:
forming an insulating film on a substrate where a first conductive film is formed;
forming a recess in the insulating film such that the first conductive film is exposed in a portion of the recess;
forming a metal oxide film to cover the insulating film and the first conductive film after forming a recess;
performing an annealing process of heating the substrate in a reducing atmosphere or an inert gas atmosphere after forming a metal oxide film;
performing a wet etching process of removing the metal oxide film formed on the first conductive film after performing an annealing process; and
forming a second conductive film in the recess after performing a wet etching process.

4. The method of claim 1, further comprising forming a third conductive film before forming a second conductive film, wherein the third conductive film includes one or more elements selected from a group comprising Fe, Co, Ni, Ru, Rh, Pd, Os, Ir and Pt.

5. The method of claim 1, wherein by performing the hydrogen radical treatment, the metal oxide film deposited on the first conductive film is reduced and a metal constituting the metal oxide film is diffused into the first conductive film, whereby the metal oxide film is removed.

6. The method of claim 1, further comprising performing an annealing process of heating the substrate in an oxidizing atmosphere after performing a hydrogen radical treatment.

7. The method of claim 2, wherein by performing the annealing process, a metal silicate film of a metal constituting the metal oxide film is formed.

8. The method of claim 1, wherein the metal oxide film includes an oxide of one or more elements selected from a group comprising Mg, Al, Ca, Ti, V, Cr, Mn, Fe, Co, Ni, Ge, Sr, Y, Zr, Nb, Mo, Rh, Pd, Sn, Ba, Hf, Ta and Ir.

9. The method of claim 1, wherein the metal oxide film includes an oxide of Mn.

10. The method of claim 1, wherein the metal oxide film is formed by ALD.

11. The method of claim 1, wherein the first conductive film and the second conductive film are made of copper or material containing copper.

12. The method of claim 1, wherein the first conductive film and the second conductive film are formed by one or more methods selected among thermal CVD, thermal ALD, plasma CVD, plasma ALD, PVD, electroplating, electroless plating, and supercritical CO_{2.}

13. The method of claim 1, wherein the hydrogen radical treatment is performed while the substrate is heated.

14. The method of claim 1, wherein the atomic hydrogen is generated by remote plasma.

15. The method of claim 3, wherein the wet etching process is performed using a neutral or acid etching liquid.

16. The method of claim 3, wherein the wet etching process is performed using an etching liquid including any one of hydrochloric acid, acetic acid and citric acid.

17. The method of claim 15, wherein the etching liquid has an oxidation-reduction potential greater than or equal to −1.2 V and less than or equal to 0.1 V.
